(19) United States
(12) Patent Application Publication
(10) Pub. No.: US 2026/0319387 A1
(43) Pub. Date: Oct. 15, 2026

(54) POSITIONING APPARATUS, LITHOGRAPHY APPARATUS, AND ARTICLE MANUFACTURING METHOD

(71) Applicant: CANON KABUSHIKI KAISHA, Tokyo (JP)

(72) Inventors: YOSHIMICHI OSUGA, Tochigi (JP); SHIGEO KOYA, Tochigi (JP); TAKAHITO CHIBANA, Tochigi (JP)

(21) Appl. No.: 19/634,218

(22) Filed: Mar. 31, 2026

(30) Foreign Application Priority Data
Apr. 14, 2025 (JP) 2025-066467

(51) Int. Cl. G03F 7/00

(52) U.S. Cl. CPC G03F 7/70758; G03F 7/0002; G03F 7/707; G03F 7/70866; G03F 7/70916; G03F 7/70933

(57) ABSTRACT

A positioning apparatus including a driving member configured to support and drive a work is provided. The apparatus includes a first part and a second part configured to relatively move in a first direction. The first part includes a first element of the driving member, and the second part includes a second element of the driving member. The apparatus further includes a cover member arranged to at least partially surround the first part and configured to extend in the first direction. The cover member includes a vent hole. On a section orthogonal to the first direction, a sectional area of a region except the first part and the second element out of a region surrounded by the cover member is not smaller than 10% of a sectional area of the first part.

### BACKGROUND

### Field of the Technology

The present disclosure relates to a positioning apparatus, a lithography apparatus, and an article manufacturing method.

### Description of the Related Art

In a positioning apparatus used in an exposure apparatus or the like, a linear motor that applies thrust to a driving target in a non-contact manner is often used as the driving device of a substrate stage that holds a substrate. The linear motor generally uses a coil that generates heat by energization, and acts as a main heat source in the exposure apparatus. If heat leaks to the optical path of an interferometer along with the driving operation of the substrate stage, temperature fluctuations occur in the optical path of the interferometer and affect the measurement accuracy.

Japanese Patent Laid-Open No. 2013-41979 discloses a positioning apparatus including a driving member including a stator and a mover connected to a moving member via a connecting member, and a housing that stores the mover and the stator. The housing of the positioning apparatus has an opening formed over the driving range of the mover, and exhaust portions. The exhaust portions are provided near two ends of the driving range, and control is performed to increase the exhaust amount from the exhaust portions in accordance with an apparatus operation, thereby reducing leakage of gas warmed by the driving member.

To improve the performance of the exposure apparatus, it is necessary to reduce the amount of gas leaking from the housing. For this purpose, the exhaust flow rate from the exhaust portions may be increased, but the increase in exhaust flow rate has a limitation.

### SUMMARY

The present disclosure provides a technique advantageous for suppressing leakage of gas warmed by a stage operation.

The present disclosure in one aspect provides a positioning apparatus including a driving member configured to support and drive a work, the positioning apparatus including a first part and a second part configured to relatively move in a first direction, the first part including a first element of the driving member, the second part including a second element of the driving member, and a cover member arranged to at least partially surround the first part and configured to extend in the first direction, and the cover member including a vent hole, wherein on a section orthogonal to the first direction, a sectional area of a region except the first part and the second element out of a region surrounded by the cover member is not smaller than 10% of a sectional area of the first part.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a plan view of a positioning apparatus;

FIGS. 2A and 2B are sectional views taken along a line A-A in FIG. 1;

FIG. 3A is a sectional view taken along a line B-B in FIG. 2A;

FIG. 3B is a sectional view taken along a line C-C in FIG. 2A;

FIGS. 4A to 4D are views showing the configurations of the positioning apparatus according to the first and second modifications;

FIGS. 5A and 5B are views showing the configuration of the positioning apparatus according to the third modification;

FIG. 6 is a view showing the configuration of the positioning apparatus according to the fourth modification;

FIG. 7 is a view showing the configuration of the positioning apparatus according to the fifth modification;

FIG. 8 is a view showing the configuration of the positioning apparatus according to the fifth modification;

FIGS. 9A and 9B are views showing the configuration of a positioning apparatus according to the second embodiment;

FIG. 10 is a view showing a configuration in which the first and second driving members support and drive a Y slider;

FIGS. 11A and 11B are views exemplifying the arrangement relationship between a plurality of driving members;

FIG. 12 is a view showing the configuration of an imprint apparatus; and

FIG. 13 is a block diagram showing the configuration of the control system of a positioning apparatus that can be assembled in the imprint apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

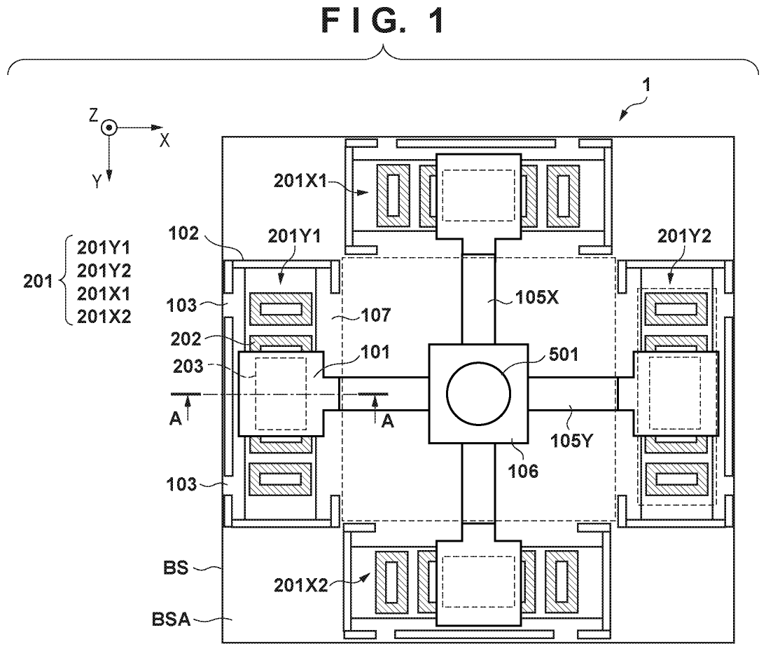

FIG. 1 is a plan view (top view) showing the configuration of a positioning apparatus 1 according to an embodiment. The positioning apparatus 1 is an apparatus that moves a work 501 (for example, a wafer or a reticle) to a desired position.

In the specification and the accompanying drawings, directions will be indicated on an XYZ coordinate system in which a horizontal surface is defined as the X-Y plane. Generally, the work 501 is placed on a support member 106 so that the surface of the work 501 becomes parallel to the horizontal surface (X-Y plane). In the following description, directions orthogonal to each other within a plane along the surface of the work 501 will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

The positioning apparatus 1 is configured to move the support member 106 supporting the work 501 on a guide surface BSA serving as the upper surface of a base BS. The guide surface BSA is a surface (surface parallel to the X-Y plane) parallel to the X and Y directions orthogonal to each other.

The positioning apparatus 1 includes an X slider 105X movable in the X direction along the guide surface BSA, and a Y slider 105Y movable in the Y direction along the guide surface BSA. The X slider 105X moves while guided by the Y slider 105Y. The Y slider 105Y holds the support member 106, and moves while guided by the X slider 105X.

The positioning apparatus 1 includes a driving member 201 that supports and drives a work. More specifically, the driving member 201 drives the support member 106 via the X slider 105X and the Y slider 105Y. The driving member 201 includes a first driving member 201Y1 that supports one end of the Y slider 105Y and drives the support member 106 in the Y direction (first direction), and a second driving member 201Y2 that supports the other end of the Y slider 105Y and drives the support member 106 in the Y direction. The driving member 201 further includes a third driving member 201X1 that supports one end of the X slider 105X and drives the support member 106 in the X direction (second direction), and a fourth driving member 201X2 that supports the other end of the X slider 105X and drives the support member 106 in the X direction.

The first driving member 201Y1 can be constituted by, for example, a linear motor. More specifically, the first driving member 201Y1 can be constituted by a linear motor including a stator including a coil 202, and a movable member 101 including a magnet 203 as a mover. One end of the Y slider 105Y is connected to the movable member 101 of the first driving member 201Y1. In this manner, the Y slider 105Y is a connecting member that connects the movable member 101 and the support member 106. A current is supplied with a proper phase to the coil 202 serving as a stator, and Lorentz force acts on the magnet of the movable member 101 to generate thrust on the movable member 101 so that the support member 106 can be moved via the Y slider 105Y. The second driving member 201Y2, the third driving member 201X1, and the fourth driving member 201X2 can also be constituted by linear motors similar to that of the first driving member 201Y1, respectively.

The first driving member 201Y1, the second driving member 201Y2, the third driving member 201X1, and the fourth driving member 201X2 have similar configurations, as described above, so the configuration and operation of the driving member 201 will be explained by paying attention to the first driving member 201Y1 representatively.

In the first driving member 201Y1, at least one coolant channel (not shown) is formed to recover, by a coolant, Joule heat generated in the coil 202 serving as a heating member. The positioning apparatus 1 includes a cover member 102 that surrounds the first driving member 201Y1. In this embodiment, the stator including the coil 202 can be formed as part of the cover member 102. For example, the coil 202 is supported (fixed) by the cover member 102. In the cover member 102, vent holes 103 are formed. The vent holes 103 are particularly used to discharge heat unrecovered by the coolant.

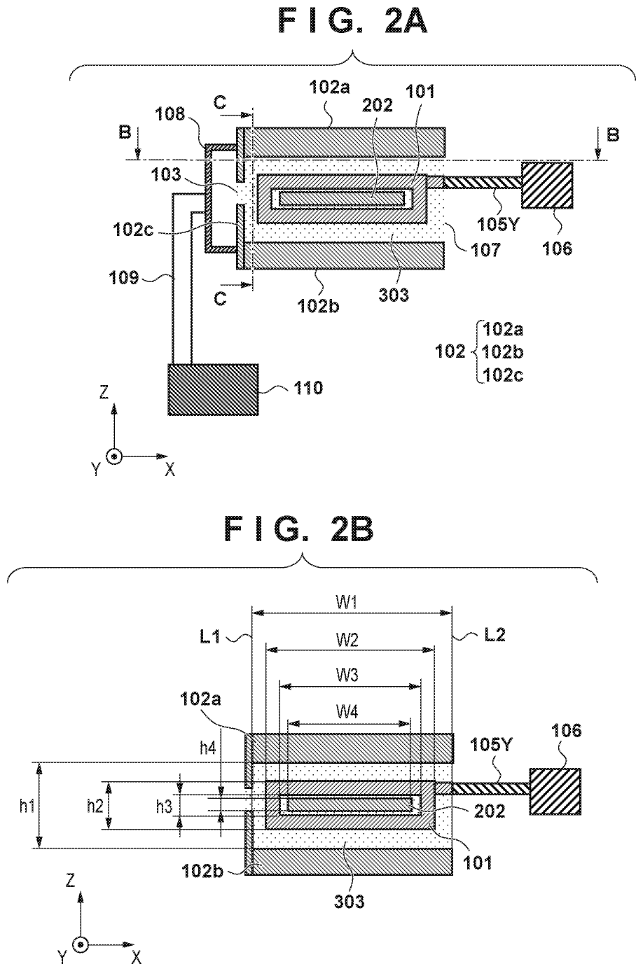

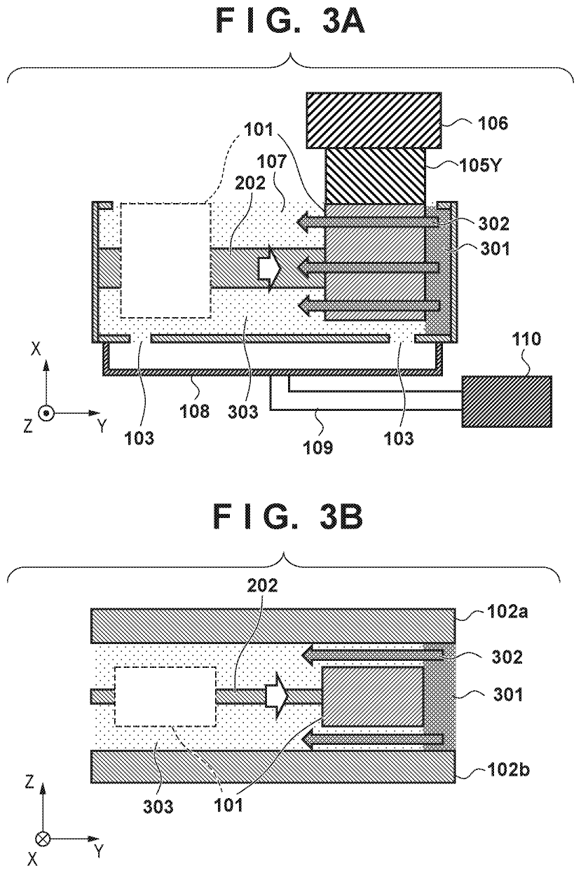

FIG. 2A is a sectional view of a main part taken along a line A-A in FIG. 1, FIG. 3A is a sectional view of the main part taken along a line B-B in FIG. 2A, and FIG. 3B is a sectional view of the main part taken along a line C-C in FIG. 2A. In FIGS. 2A and 2B, a direction vertical to the sheet surface is the Y direction (first direction). In FIGS. 3A and 3B, the left-and-right direction of the sheet surface is the Y direction (first direction).

The positioning apparatus 1 includes the first part and the second part that relatively move in the first direction (for example, Y direction). The first part can include the first element of the driving member 201, and the second part can include the second element of the driving member 201 and a cover member that extends in the first direction and is arranged to at least partially surround the first part. In the following example, the first part, that is, the first element of the driving member 201 is the movable member 101. The second part can include the stator (second element of the driving member 201) including the coil 202, and a cover member 102 that extends in the first direction and is arranged to at least partially surround the movable member 101 (first part).

As shown in FIGS. 2A and 2B and FIGS. 3A and 3B, the positioning apparatus 1 includes the movable member 101 and the cover member 102 that relatively move in the Y direction (first direction). The cover member 102 can include an upper cover 102a (first cover) and a lower cover 102b (second cover) that extend in the Y direction and are arranged to sandwich the space of the movable range of the movable member 101 in the Y direction. As shown in FIG. 2A, the upper cover 102a covers the top of the movable member 101, and the lower cover 102b covers the bottom of the movable member 101. Further, the cover member 102 can include an outer wall member 102c that connects the upper cover 102a and the lower cover 102b at one end (end portion of the base BS on the left side in FIG. 1) in the X direction. That is, the outer wall member 102c connects end portions of the upper cover 102a and lower cover 102b on a side opposite to the support member side. At the other ends of the upper cover 102a and lower cover 102b in the X direction (end portions on the support member 106 side), the end portions are not connected by the outer wall member, and an opening portion 107 serving as a moving space for the movable member 101 and the Y slider 105Y in the Y direction is formed. A space 303 is formed between the movable member 101 and the cover member 102. The vent holes 103 can be formed near two ends of the outer wall member 102c in the Y direction. The vent holes 103 can function as exhaust ports for exhaust particularly from the space 303. The vent hole 103 (when there are a plurality of vent holes 103, at least one of them) is connected to an exhaust member 108. The exhaust member 108 is connected to a vacuum source 110 via a duct 109 (for example, a tube or a corner duct), and provides a gas flow path between the vent hole 103 and the vacuum source 110. By the operation of the vacuum source 110, gas in the space 303 can be forcibly exhausted from the vent hole 103.

A case where the movable member 101 moves from a region indicated by a broken line to a region indicated by a solid line, as shown in FIGS. 3A and 3B, will be considered. At this time, the side surface of the movable member 101 pushes air. In this embodiment, the space 303 is provided between the movable member 101 and the cover member 102 (see FIG. 2A), so the airflow 302 of pushed air 301 flowing to the space 303 is formed. This suppresses leakage of gas warmed by the driving member 201 from the opening portion 107.

The size relationship between the cover member 102, the movable member 101, and the stator including the coil 202 will be explained with reference to FIG. 2B. FIG. 2B is a sectional view of the same section (X-Z plane) orthogonal to the Y direction as that in FIG. 2A. The following description will represent that the sectional area of a region except the movable member is equal to or larger than 10% of the sectional area of the movable member in a region sandwiched between the upper cover 102a and the lower cover 102b on the X-Z plane.

In FIG. 2B, auxiliary lines L1 and L2 are virtual lines clearly indicating the width of a space (to be referred to as the internal space of the cover member 102) sandwiched between the upper cover 102a and the lower cover 102b in the X direction. The auxiliary line L1 is the first virtual line passing through one end of the upper cover 102a and one end of the lower cover 102b in the X direction (second direction) orthogonal to the Y direction (first direction). The auxiliary line L2 is the second virtual line passing through the other end of the upper cover 102a and the other end of the lower cover 102b. The boundary of the internal space of the cover member 102 in the X direction is defined by the auxiliary lines L1 and L2. W1 represents a distance between the auxiliary lines L1 and L2, that is, a width of the internal space of the cover member 102 in the X direction. h1 represents a height of the internal space of the cover member 102 in the Z direction. W2 represents a width of the movable member 101 in the X direction, and h2 represents a height of the movable member 101 in the Z direction. W3 represents a width of a hollow portion formed in the movable member 101 in the X direction, and h3 represents a height of the hollow portion in the Z direction. W4 represents a width of the stator containing the coil 202 in the X direction, and h4 represents a height of the stator in the Z direction. The sectional area of the space 303 is

W1×h1−W2×h2+W3×h3−W4×h4

The sectional area of the movable member 101 is

W2×h2−W3×h3

The sectional area of the movable member 101 is an area by which air is pushed when the movable member 101 operates. The sectional area of the space 303 is the area of a region where the air pushed by the operation of the movable member 101 flows. In this embodiment, the sectional area of the space 303 is equal to or larger than 10% of the sectional area of the movable member 101 in order to suppress leakage of gas from the opening portion 107. To effectively suppress leakage of gas from the opening portion 107, the sectional area of the space 303 is preferably equal to or larger than 40% of the sectional area of the movable member 101, more preferably equal to or larger than 70%, and further preferably equal to or larger than 100%.

Although the section of the space 303 and that of the movable member 101 have rectangular shapes in the description of FIG. 2B, the shapes of the sections are not limited to them. In an actual apparatus, notches or protrusions are sometimes provided at the respective portions of the linear motor and cover member, or sometimes formed from curved surfaces. Regardless of the shape, the sectional area of the space 303 is set to be equal to or larger than 10% of the sectional area of the movable member 101. This can also suppress leakage of gas from the opening portion 107, and the shapes of the sections can be arbitrarily determined.

The ratio of the sectional area of the space 303 to that of the movable member 101 can be determined in accordance with the relative driving speed of the movable member 101 and cover member 102. It is preferable to increase the ratio of the sectional area of the space 303 to that of the movable member 101 as the relative driving speed becomes higher. When the ratio of the sectional area of the space 303 to that of the movable member 101 becomes higher than 100%, the volume of the space 303 becomes larger than that of pushed air, and leakage of gas from the opening portion 107 can be suppressed regardless of the relative driving speed.

The ratio of the sectional area of the space 303 to that of the movable member 101 can be determined in accordance with the relative driving speed, the arrangement restriction between the cover member 102 and members arranged around it, and the like. Note that an excessively large sectional area of the space 303 may upsize the apparatus. To suppress the upsizing of the apparatus, the sectional area of the space 303 is preferably equal to or smaller than five times of the sectional area of the movable member 101. The sectional area of the space 303 is more preferably equal to or smaller than three times of the sectional area of the movable member 101, and further preferably equal to or smaller than two times.

A method of determining the sectional area of the movable member 101, that of the space 303, and the relative driving speed of the movable member 101 and cover member 102 will be explained.

Here, in the region sandwiched between the upper cover 102a and the lower cover 102b on the section orthogonal to the Y direction, Sm represents the sectional area of the movable member 101, and Sv represents the sectional area (sectional area of a region except the movable member) of the space 303. In addition, V represents the relative driving speed of the movable member 101 and cover member 102, ΔP represents the pressure difference between the internal space (first space) of the cover member 102 and its external space (second space), and p represents the density of gas in the cover member 102 (in the first space).

In this case, the sectional area Sm of the movable member 101, the sectional area Sv of the space 303, and the relative driving speed V of the movable member 101 and cover member 102 are determined to satisfy the following relation:

$$\frac{1}{2} ρ {V}^{2} \frac{{S}_{m} - {S}_{v}}{{S}_{m}} < Δ P \qquad ( 1 )$$

Note that the relative driving speed V is regarded as the maximum speed of relative driving of the movable member 101 and cover member 102.

Satisfying the above relation can suppress the pressure rise of the air 301 generated by relative driving of the movable member 101 and cover member 102, and suppress leakage of warmed gas from the opening portion 107.

The condition for suppressing leakage of gas from the opening portion 107 has been explained using the ratio of the sectional area of the space 303 to that of the movable member 101 in the above example, but can also be explained using a gap height instead of the sectional area. For example, gap heights (h1−h2+h3−h4) between the movable member 101 and the cover member 102 and between the movable member 101 and the stator including the coil 202, and a side surface height h2−h3 of the movable member 101 can be used. To suppress leakage of gas from the opening portion 107, h1−h2+h3−h4 is preferably equal to or larger than 10% of h2−h3. To effectively suppress leakage of gas from the opening portion 107, h1−h2+h3−h4 is preferably equal to or larger than 40% of h2−h3, further preferably equal to or larger than 70%, and still further preferably equal to or larger than 100%. In this fashion, when the height is used, calculation of the sectional area can be omitted. Particularly when the shape of the section is complicated, the design can be made efficiently. Note that FIG. 2B is referred to, so the condition for suppressing leakage of gas from the opening portion 107 has been expressed by the gap height, but can also be expressed by something other than the height. When something other than the height is applied, h1−h2+h3−h4 can be the distance between the long side of the movable member 101 and the cover member arranged outside to face it, and h2−h3 can be the thickness of the movable member 101 along the long side.

The configuration and operation of the driving member 201 have been explained by paying attention to the first driving member 201Y1 representatively. One end of the Y slider 105Y is supported by the first driving member 201Y1, and the other end of the Y slider 105Y is supported by the second driving member 201Y2. FIG. 10 shows a configuration in which the first driving member 201Y1 and the second driving member 201Y2 support and drive the Y slider 105Y. Similar to the first driving member 201Y1, the second driving member 201Y2 is also surrounded by the cover member 102.

In this way, a plurality of driving members (actuators) surrounded by the cover member can be arranged in the same axial direction to suppress heat generation of the actuators that generate thrust, suppressing the amount of heat unrecoverable by the coolant. Thus, leakage of warmed gas can be suppressed more effectively. The number of driving members surrounded by the cover member that are arranged in the same axial direction can be arbitrarily determined, and can be determined in consideration of the amount of heat unrecoverable by the coolant, and the like.

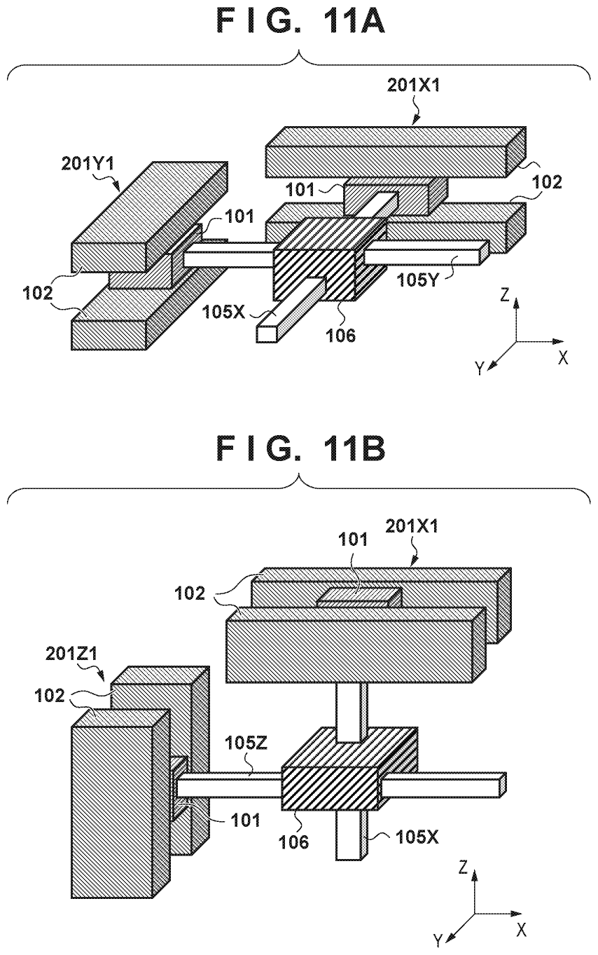

FIG. 11A shows the arrangement relationship between the first driving member 201Y1 that supports and drives the Y slider 105Y, and the third driving member 201X1 that supports and drives the X slider 105X. Similar to the first driving member 201Y1, the third driving member 201X1 is also surrounded by the cover member 102. Although not shown, the fourth driving member 201X2 is also similarly surrounded by the cover member 102.

The embodiment in the configuration in which the positioning apparatus 1 moves the support member 106 in a direction parallel to the X-Y plane along the guide surface BSA has been described. However, the present disclosure can also take a configuration in which the support member 106 is moved in a direction parallel to the X-Z plane or the Y-Z plane. Although the Y direction is the first direction and the X direction is the second direction in the above-described example, the first direction and the second direction are interchangeable among the X, Y, and Z directions. FIG. 11B shows a configuration example in which the support member 106 is moved in a direction parallel to the X-Z plane. This is equivalent to a configuration obtained by rotating the configuration in FIG. 11A by 90° about the X-axis. In this case, a fifth driving member 201Z1 that drives a Z slider 105Z in the Z direction is arranged instead of the first driving member 201Y1. Similar to the third driving member 201X1, the fifth driving member 201Z1 is also surrounded by the cover member 102.

In this fashion, an axial direction in which the driving member is arranged is arbitrary. Regardless of the axial direction in which the driving member is arranged, a space is formed between the movable member 101 and the cover member 102, and leakage of warmed gas from the opening portion 107 can be suppressed.

### (First Modification)

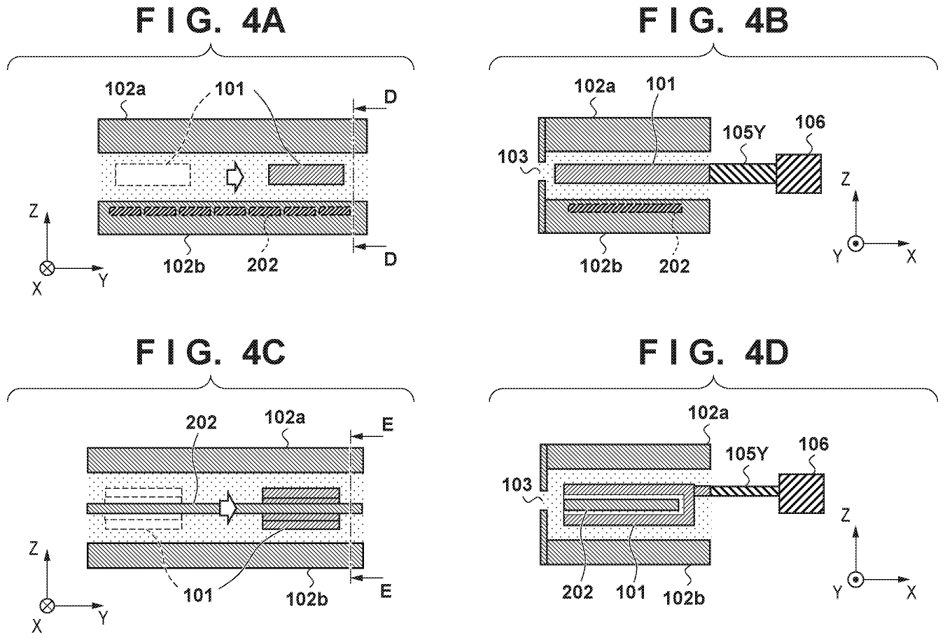

The first modification of the first embodiment will be described with reference to FIGS. 4A and 4B. In the configuration shown in FIGS. 2A and 2B, the coil 202 serving as a stator is arranged in the hollow portion of the movable member 101. To the contrary, the coil 202 is arranged outside a movable member 101a in the first modification. FIG. 4A is a side sectional view corresponding to FIG. 3B, and FIG. 4B is a sectional view taken along a line D-D in FIG. 4A. In the first modification, the coil 202 serving as a stator is arranged inside the cover member 102, as shown in FIGS. 4A and 4B.

The magnet 203 serving as a mover is arranged inside the movable member 101, a current is supplied with a proper phase to the coil 202 serving as a stator, and Lorentz force acts on the magnet 203 to generate thrust on the movable member 101, which is similar to the positioning apparatus in FIGS. 2A and 2B. The first modification has an advantage of making the apparatus compact by arranging the coil inside the cover 102b arranged below the movable member 101. Even in this case, a space is formed between the movable member 101 and the cover member 102, and leakage of warmed gas from the opening portion 107 can be suppressed. The coil 202 is arranged inside the lower cover 102b in the example of FIGS. 4A and 4B, but may be arranged inside the upper cover 102a. The arrangement of the coil 202 can be freely determined in consideration of the arrangement restriction with other members, and the like.

### (Second Modification)

Next, the second modification will be explained with reference to FIGS. 4C and 4D. FIG. 4C is a side sectional view corresponding to FIG. 4A, and FIG. 4D is a sectional view taken along a line E-E in FIG. 4C. In the second modification, the movable member 101 is arranged to surround three sides of the coil 202 serving as a stator. The second modification has an advantage of allowing easy detachment of the movable member 101 in maintenance of the apparatus. When detaching the movable member 101 in the configuration shown in FIG. 2A, the movable member 101 and the coil 202 serving as a stator formed as part of the cover member 102 need to be detached simultaneously. In contrast, in the configuration shown in FIG. 4D according to the second modification, the movable member 101 can be detached without detaching the coil 202 serving as a stator formed as part of the cover member 102, thus improving the maintainability. Note that even when the movable member 101 is arranged to surround three sides of the coil 202 serving as a stator formed as part of the cover member 102, a space is formed between the movable member 101 and the cover member 102. This can suppress leakage of warmed gas from the opening portion 107.

### (Third Modification)

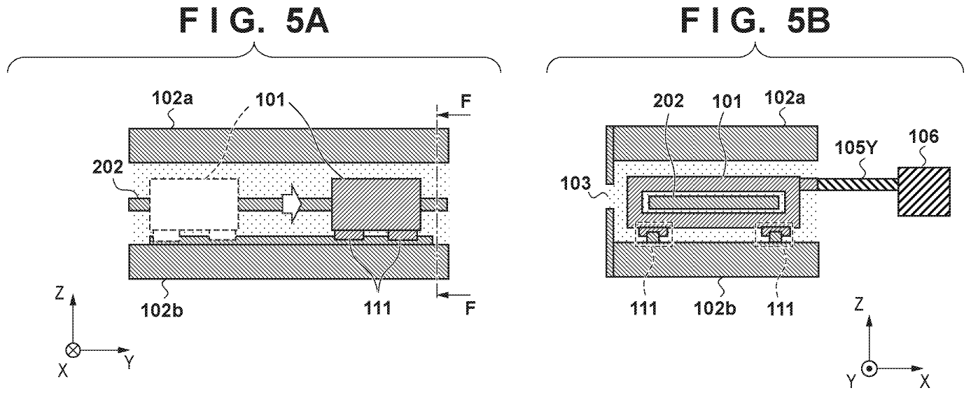

Next, the third modification will be explained with reference to FIGS. 5A and 5B. The third modification will describe an example in which the driving member 201 is an actuator other than the above-described linear motor.

FIG. 5A is a side sectional view corresponding to FIGS. 4A and 4C, and FIG. 5B is a sectional view taken along a line F-F in FIG. 5A. When the relative driving method of the movable member 101 and cover member 102 is magnetic levitation by a linear motor, the movable member 101 and the cover member 102 need not contact each other. However, a method other than the non-contact method may be adopted as the relative driving method. For example, a driving method using a ball screw and a motor may be adopted. In this case, for example, the movable member 101 contacts the cover member 102 (lower cover 102b in the case of FIGS. 5A and 5B) via guide members 111. As the guide members 111, for example, a linear guide or a ball bearing is used.

In this way, the relative driving method of the movable member 101 and cover member 102 can be freely selected. Even in the positioning apparatus shown in FIGS. 5A and 5B, a space can be formed between the movable member 101 and the cover member 102. This can suppress leakage of warmed gas from the opening portion 107 regardless of contact or non-contact of the movable member 101 and cover member 102.

### (Fourth Modification)

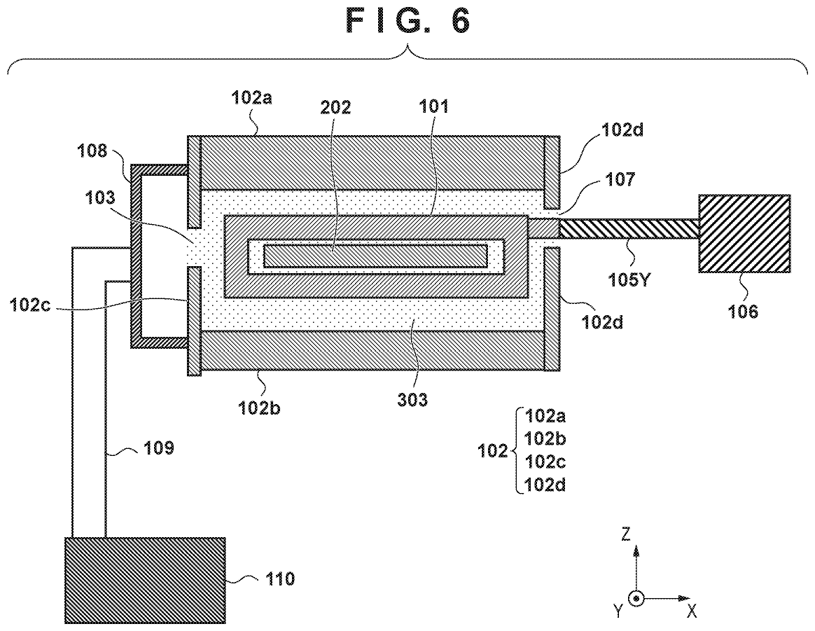

Next, the fourth modification of the positioning apparatus in FIGS. 2A and 2B according to the first embodiment will be explained with reference to FIG. 6. FIG. 6 is a sectional view corresponding to FIG. 2A. In the fourth modification, the cover member 102 further includes wall members 102d arranged at end portions of the upper cover 102a and lower cover 102b on the support member side in the X direction. The wall members 102d reduce the width of the opening portion 107 in the Z direction and decrease the area of the opening portion 107. Decreasing the area of the opening portion 107 has an advantage of further increasing the pressure difference between the internal space and external space of the cover member 102 evacuated from the vent holes 103. Increasing the pressure difference can more effectively suppress leakage of warmed gas from the opening portion 107. The size of the opening portion 107 can be determined in consideration of the tolerances of the Y slider 105Y and wall members 102d and the like so that the Y slider 105Y and the wall members 102d do not contact each other.

### (Fifth Modification)

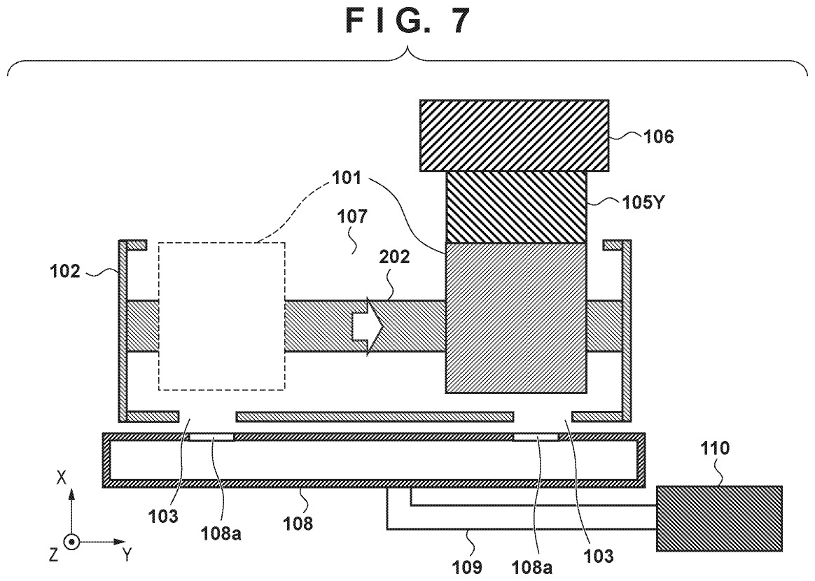

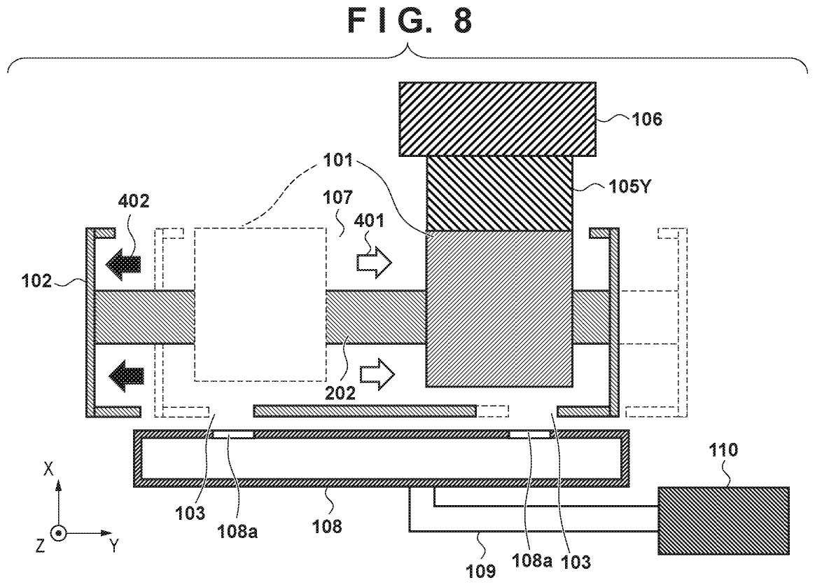

The fifth modification will be explained with reference to FIGS. 7 and 8. FIG. 7 is a top sectional view corresponding to FIG. 3A, and shows a state in which the movable member 101 is driven (moved) relatively to the cover member 102 (and the coil 202) in the Y direction. In the fifth modification, the exhaust member 108 is arranged in non-contact with the cover member 102. Intake holes 108a communicating with the gas flow path of the exhaust member 108 are provided at positions of the exhaust member 108 facing the vent holes 103.

An effect of arranging the exhaust member 108 in non-contact with the cover member 102 will be explained with reference to FIG. 8. FIG. 8 shows a state in which the movable member 101 is driven relatively to the cover member 102 in the Y direction. When the movable member 101 is driven relatively to the cover member 102, thrust 401 and a reaction force 402 are generated. The cover member 102 (and the coil 202) can move in the Y direction. By arranging the exhaust member 108 in non-contact with the cover member 102, the cover member 102 is driven by the reaction force 402 in a direction opposite to the movable member 101. In this manner, the cover member 102 functions as a counter mass mechanism. The counter mass mechanism suppresses vibrations externally transferred from the positioning apparatus 1 when the cover member 102 is driven in a direction opposite to the moving direction of the movable member 101 in response to driving of the Y slider 105Y connected to the support member 106 and the movable member 101. When the positioning apparatus 1 is used in a lithography apparatus such as an exposure apparatus, vibrations transferred from the positioning apparatus 1 to a structure member can be suppressed advantageously. Note that another driving source for return to an original position against driving by the reaction force 402 may be provided for the cover member 102. Note that the sizes and positional relationship of the vent holes 103 and the intake holes 108a of the exhaust member 108 are determined so that exhaust from the vent holes 103 becomes possible even upon movement by the reaction force. The arrangement and shape around the cover member 102 can be freely determined in accordance with the arrangement restriction between the cover member 102 and other members, and the apparatus performance. Even in this case, a space is formed between the movable member 101 and the cover member 102, and leakage of warmed gas from the opening portion 107 can be effectively suppressed.

### Second Embodiment

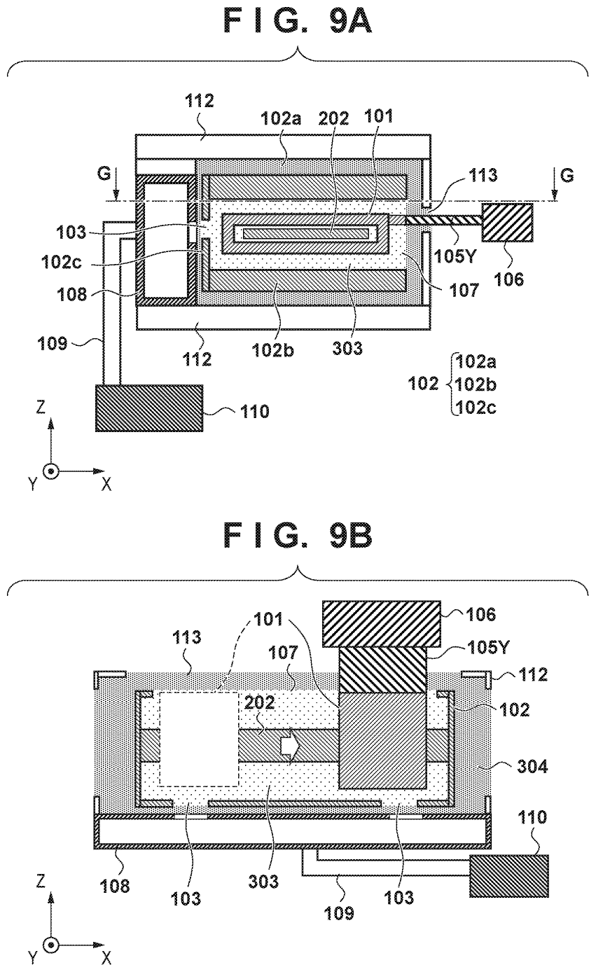

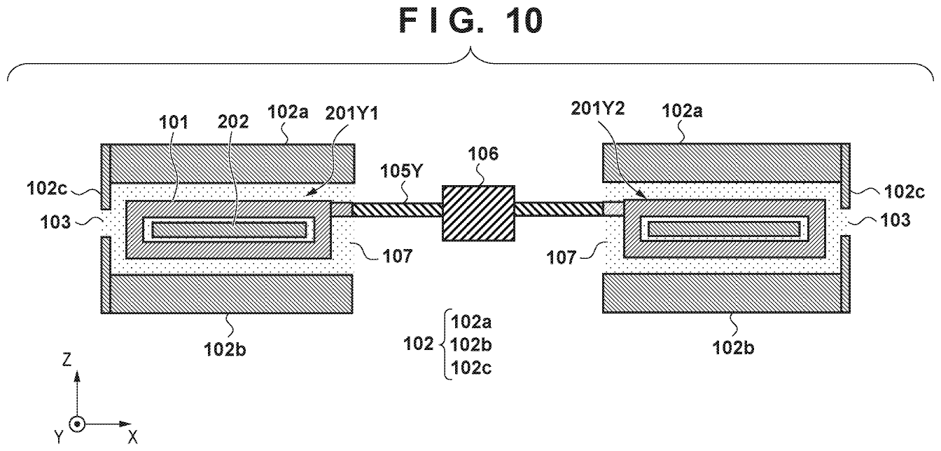

A positioning apparatus according to the second embodiment will be explained with reference to FIGS. 9A and 9B. FIG. 9A is a sectional view corresponding to FIG. 2A. FIG. 9B is a sectional view taken along a line G-G in FIG. 9A, and corresponds to FIG. 3A. In the second embodiment, a container 112 is arranged to contain a movable member 101 and a cover member 102. A space 304 is provided between the cover member 102 and the container 112. The container 112 may include an exhaust member 108. The exhaust member 108 is arranged in non-contact with the cover member 102. In the container 112, an opening portion 113 (second opening portion) adjacent to an opening portion 107 of the cover member 102 is so formed as to ensure the moving space of the movable member 101 and a Y slider 105Y.

In the configuration of the positioning apparatus according to the second embodiment, the space 304 formed between the cover member 102 and the container 112, and the opening portion 113 are provided outside a space 303. This can more reliably suppress leakage of gas.

### Third Embodiment

The above-described positioning apparatus 1 is applicable to a substrate positioning apparatus (substrate stage) in an imprint apparatus and a lithography apparatus such as an exposure apparatus, and may also be applied to another apparatus such as a processing apparatus, an inspection apparatus, or a microscope. An example in which a positioning apparatus 1 is applied to an imprint apparatus will be explained.

An imprint apparatus is an apparatus that brings an imprint material on a substrate into contact with a mold and applies curing energy to the imprint material, thereby forming the pattern of a cured product to which the convex-concave pattern of the mold is transferred. The imprint material can be a curable composition (to be also referred to as an uncured resin) that is cured by receiving curing energy. The curing energy can be an electromagnetic wave, heat, or the like. The electromagnetic wave can be, for example, light (infrared rays, visible light rays, ultraviolet rays, or the like) whose wavelength is selected from the range of 10 nm (inclusive) to 1 mm (inclusive).

The curable composition is a composition cured by receiving the curing energy such as the electromagnetic wave or heat. Of such curable compositions, a photo-curable composition cured by light contains at least a polymerizable compound and a photopolymerization initiator, and may further contain a nonpolymerizable compound or a solvent, as needed. The nonpolymerizable compound can be at least one material selected from the group consisting of a sensitizer, a hydrogen donor, an internal mold release agent, a surfactant, an antioxidant, and a polymer component.

The imprint material can be applied like a film onto a substrate by a spin coater or a slit coater. Alternatively, the imprint material can be supplied from a liquid injection head onto a substrate, like a droplet or an island or film formed by connecting a plurality of droplets. The viscosity (viscosity at 25° C.) of the imprint material can be, for example, 1 mPa·s (inclusive) to 100 mPa·s (inclusive).

The substrate can be a member formed from glass, ceramic, a metal, a semiconductor, a resin, or the like. A layer formed from a material different from that of the member may be formed on the surface of the member, as needed. The substrate can be, for example, a silicon wafer, a compound semiconductor wafer, or a silica glass plate.

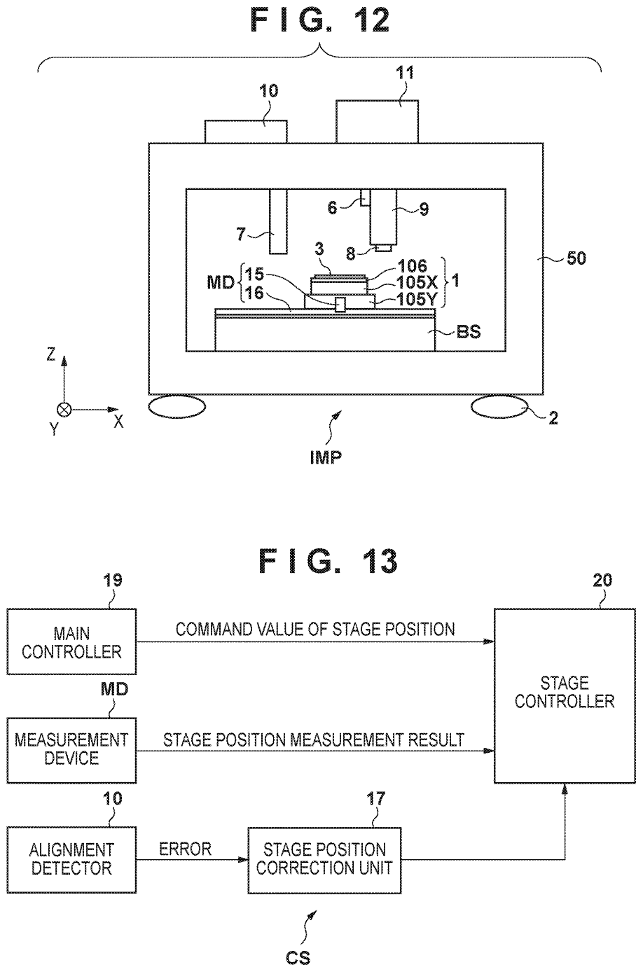

FIG. 12 schematically shows the configuration of an imprint apparatus IMP. A main body structure 50 of the imprint apparatus IMP is installed on a floor via a plurality of (typically three or four) vibration isolators 2. A substrate 3 (corresponding to a work 501) is placed on a substrate chuck (not shown) mounted on a support member 106 of a positioning apparatus 1. The substrate 3 is placed on the substrate chuck so that the surface of the substrate 3 becomes parallel to the horizontal plane (X-Y plane). The positioning apparatus 1 can have strokes along the X-axis and the Y-axis enough to move the substrate 3 to a substrate replacement position for loading and unloading the substrate 3, and a dropping position for arranging an imprint material on the substrate 3.

The positioning apparatus 1 can include a base BS, an X slider 105X that is arranged on the base BS and moves in the X direction, and a Y slider 105Y movable in the Y direction. The X slider 105X and the Y slider 105Y are arranged on the base BS. For example, the position of the X slider 105X is measured by a measurement device MD, such as a linear encoder, including a detection head 15 that moves together with the X slider 105X, and a scale 16 provided on the base BS. Similarly, the position of the Y slider 105Y can be measured by a measurement device, such as a linear encoder, including a detection head that moves together with the Y slider 105Y, and a scale provided on the X slider 105X. Instead of these linear encoders, laser interferometers each of which can be constituted by a laser head and a mirror provided on the X slider 105X or the Y slider 105Y may be provided.

The imprint material can be supplied or arranged onto a shot region of the substrate 3 by a supply unit 7 (dispenser). The imprint material may be supplied or arranged onto a shot region of the substrate 3 by an external device of the imprint apparatus IMP. The shot region is a region where a pattern is formed by one imprint processing in the imprint apparatus IMP. The imprint processing can include an operation of bringing a mold 8 (master) into contact with the imprint material on the substrate, and an operation of separating the mold 8 from the cured imprint material.

The imprint apparatus IMP can include an imprint head 9 that drives the mold 8. The imprint head 9 can be configured to hold the mold 8 and drive it about a plurality of axes (for example, six, X-axis, Y-axis, Z-axis, OX-axis, OY-axis, and OZ-axis). The imprint head 9 can drive the mold 8 about the Z-axis to control contact of the mold 8 to an imprint material on the substrate 3 and separation of the mold 8 from the cured imprint material on the substrate 3.

The imprint apparatus IMP can include, near the imprint head 9, a sensor 6 that detects displacements of the mold 8 in the X and Y directions. The imprint apparatus IMP can also include an alignment detector 10 that detects the relative positions of the mold 8 and a shot region of the substrate 3 in the X and Y directions. The substrate 3 on which a layer is formed by the lithography apparatus has an alignment mark. The alignment detector 10 can be configured to detect the relative positions of a shot region of the substrate 3 and the mold 8 using the alignment mark of the substrate 3 and that of the mold 8.

The imprint apparatus IMP can include a curing unit 11 that supplies, to an imprint material, energy for curing the imprint material. After the mold 8 is brought into contact with the imprint material on the substrate 3 to fully fill the concave portions of the convex-concave pattern of the mold 8 with the imprint material, the curing unit 11 supplies, to the imprint material, energy for curing the imprint material.

FIG. 13 exemplifies a control system CS of the positioning apparatus 1. The operation of the control system CS will be explained together with that of the imprint apparatus IMP. A stage controller 20 can perform control of the position of the substrate 3. The stage controller 20 can constitute a feedback control system that controls the positioning apparatus 1 based on the deviation between the command value of a stage position (position of the substrate 3) sent from a main controller 19, and a stage position measurement result by the measurement device MD.

First, the main controller 19 supplies, to the stage controller 20, a stage position command value representing a substrate replacement position, and the stage controller 20 moves the substrate 3 based on the command value and a stage position measurement result supplied from the measurement device MD. At the substrate replacement position, the substrate 3 is mounted on a substrate chuck on the support member 106 by a conveyance mechanism (not shown). At this time, the substrate 3 can be arranged on the substrate chuck with an error about the X-axis, the Y-axis, and the OZ-axis because of the positioning accuracy of the conveyance mechanism. The error can be measured by detecting, by the alignment detector 10, the relative positions of a reference mark (not shown) provided on the support member 106 and the alignment mark of the substrate 3.

The error measured by the alignment detector 10 is sent to a stage position correction unit 17. The stage position correction unit 17 provides the error as an offset value to the stage controller 20. The stage controller 20 can correct, by the offset value, the stage position command value from the main controller 19, thereby canceling the above-mentioned error. Instead of this operation, the position of the mold 8 may be adjusted by the imprint head 9 based on an error measured by the alignment detector 10. Alternatively, the error may be canceled by both control of the support member 106 by the stage controller 20 and control of the mold 8 by the imprint head 9 based on an error measured by the alignment detector 10.

Then, the main controller 19 controls the positioning apparatus 1 via the stage controller 20 to position the shot region of the substrate 3 below the supply unit 7, and controls the supply unit 7 to supply the imprint material onto the shot region. After that, the main controller 19 controls the positioning apparatus 1 via the stage controller 20 to position the shot region immediately below the mold 8, and controls the imprint head 9 to bring the mold 8 into contact with the imprint material on the shot region. Here, in one example, the gap between the upper surface of the substrate 3 and the pattern surface of the mold 8 is set to be 1 μm or less, and the imprint material on the substrate 3 and the mold 8 come into contact with each other to fill the concave portions of the convex-concave pattern of the pattern surface with the imprint material.

Immediately after the imprint material on the substrate 3 and the pattern surface of the mold 8 contact each other, the relative position deviation between the mold 8 and the shot region of the substrate 3 is large. The position deviation is measured by the alignment detector 10, and the positioning apparatus 1 is controlled via the stage position correction unit 17 and the stage controller 20 based on the measurement result. By repeating this operation, the relative position deviation between the mold 8 and the shot region of the substrate 3 can fall within an allowable range. Instead of this operation, the imprint head 9 may adjust the position of the mold 8 to decrease the relative position deviation based on an error measured by the alignment detector 10. The relative position deviation may be controlled by both control of a top plate 28 by the stage controller 20 and control of the mold 8 by the imprint head 9 based on an error measured by the alignment detector 10.

After the relative position deviation between the mold 8 and the shot region of the substrate 3 falls within the allowable range, the main controller 19 controls the curing unit 11 to supply the curing energy to the imprint material, thereby curing the imprint material. Then, the main controller 19 controls the imprint head 9 to separate the mold 8 from the cured imprint material.

### Embodiment of Article Manufacturing Method

An article manufacturing method will be described below. As an example, an article manufacturing method of manufacturing a device (for example, a semiconductor integrated circuit element or a liquid crystal display element) as an article will be explained. The article manufacturing method includes a step of forming a pattern on a substrate (wafer, glass plate, or film-shaped substrate) using a lithography apparatus such as the above-described imprint apparatus. The manufacturing method can further include a step of processing (for example, etching) the pattern-formed substrate. Note that when manufacturing another article such as a patterned medium (recording medium) or an optical element, the manufacturing method can include another process of processing the pattern-formed substrate in place of etching.

The pattern of a cured product formed using the imprint apparatus serving as a lithography apparatus is used permanently for at least some of various articles or temporarily when manufacturing various articles. Examples of the article are an electric circuit element, an optical element, a MEMS, a recording element, a sensor, and a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. The mold is an imprint mold or the like.

The pattern of the cured product is directly used as at least some of the constituent members of the above-described article or used temporarily as a resist mask. After etching, ion implantation, or the like is performed in the substrate processing step, the resist mask is removed.

The present disclosure can provide a technique advantageous for suppressing leakage of gas warmed by a stage operation.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-066467, filed on Apr. 14, 2025 which is hereby incorporated by reference herein in its entirety.

What is claimed is:

1. A positioning apparatus including a driving member configured to support and drive a work, the positioning apparatus comprising:
a first part and a second part configured to relatively move in a first direction,
the first part including a first element of the driving member,
the second part including a second element of the driving member, and a cover member arranged to at least partially surround the first part and configured to extend in the first direction, and
the cover member including a vent hole,
wherein on a section orthogonal to the first direction, a sectional area of a region except the first part and the second element out of a region surrounded by the cover member is not smaller than 10% of a sectional area of the first part.

2. The apparatus according to claim 1, wherein the first part is a movable member in the driving member, and
the positioning apparatus further comprises:
a support member configured to support the work; and
a connecting member configured to connect the movable member and the support member.

3. The apparatus according to claim 2, wherein the cover member includes:
a first cover and a second cover arranged to sandwich a space of a movable region of the movable member in the first direction, and configured to extend in the first direction; and
an outer wall member configured to connect end portions of the first cover and the second cover on a side opposite to a side of the support member, and
the vent hole is formed in the outer wall member.

4. The apparatus according to claim 3, wherein the cover member includes an opening portion formed at an end portion on the side of the support member, and
the opening portion is formed between the first cover and the second cover to become a moving space of the connecting member in the first direction.

5. The apparatus according to claim 4, wherein the cover member further includes a wall member arranged at end portions of the first cover and the second cover on the side of the support member, and configured to form the opening portion.

6. The apparatus according to claim 2, wherein the driving member is an actuator configured to apply thrust to the movable member.

7. The apparatus according to claim 6, wherein the actuator is a linear motor.

8. The apparatus according to claim 6, further comprising an exhaust member connected to a vacuum source and configured to provide a gas flow path between the vent hole and the vacuum source.

9. The apparatus according to claim 8, wherein the exhaust member is arranged in non-contact with the cover member, and includes an intake hole communicating with the gas flow path at a position facing the vent hole.

10. The apparatus according to claim 9, wherein the second part moves by a reaction force of the thrust in a direction opposite to the movable member.

11. The apparatus according to claim 4, further comprising a container configured to contain the cover member,
wherein a space is formed between the cover member and the container, and
a second opening portion adjacent to the opening portion is formed in the container to ensure the moving space.

12. The apparatus according to claim 3, wherein the region surrounded by the cover member is a region defined by a first virtual line passing through one end of the first cover and one end of the second cover in a second direction orthogonal to the first direction, and a second virtual line passing through the other end of the first cover and the other end of the second cover.

13. A positioning apparatus comprising:
a movable member;
a driving member configured to drive the movable member in a first direction;
a cover member arranged to sandwich a space of a movable region of the movable member in the first direction, configured to extend in the first direction, and including a first cover and a second cover; and
a vent hole formed in the cover member,
wherein in a region sandwiched between the first cover and the second cover on a section orthogonal to the first direction, letting Sm be a sectional area of the movable member, Sv be a sectional area of a region except the movable member, V be a relative driving speed of the movable member and the cover member, ΔP be a pressure difference between a first space sandwiched by the first cover and the second cover and a second space outside the first space, and p be a density of gas in the first space, a relation:
$$\frac{1}{2} ρ {V}^{2} \frac{{S}_{m} - {S}_{v}}{{S}_{m}} < Δ P \qquad ( 1 )$$
is satisfied.

14. The apparatus according to claim 13, further comprising:
a support member configured to support a work; and
a connecting member configured to connect the movable member and the support member.

15. The apparatus according to claim 14, wherein the cover member further includes an outer wall member configured to connect end portions of the first cover and the second cover on a side opposite to a side of the support member, and
the vent hole is formed in the outer wall member.

16. The apparatus according to claim 14, wherein the cover member includes an opening portion formed at an end portion on the side of the support member, and
the opening portion is formed between the first cover and the second cover to become a moving space of the connecting member in the first direction.

17. The apparatus according to claim 16, wherein the cover member further includes a wall member arranged at end portions of the first cover and the second cover on the side of the support member, and configured to form the opening portion.

18. The apparatus according to claim 13, wherein the driving member is an actuator configured to apply thrust to the movable member.

19. The apparatus according to claim 18, wherein the actuator is a linear motor.

20. The apparatus according to claim 18, further comprising an exhaust member connected to a vacuum source and configured to provide a gas flow path between the vent hole and the vacuum source.

21. The apparatus according to claim 20, wherein the exhaust member is arranged in non-contact with the cover member, and includes an intake hole communicating with the gas flow path at a position facing the vent hole.

22. The apparatus according to claim 21, wherein the cover member moves by a reaction force of the thrust in a direction opposite to the movable member.

23. The apparatus according to claim 16, further comprising a container configured to contain the cover member,
wherein a space is formed between the cover member and the container, and
a second opening portion adjacent to the opening portion is formed in the container to ensure the moving space.

24. The apparatus according to claim 13, wherein the region sandwiched by the first cover and the second cover is a region defined by a first virtual line passing through one end of the first cover and one end of the second cover in a second direction orthogonal to the first direction, and a second virtual line passing through the other end of the first cover and the other end of the second cover.

25. A lithography apparatus comprising:
a positioning apparatus defined in claim 1; and
a substrate chuck mounted on the positioning apparatus,
wherein the lithography apparatus is configured to transfer a pattern of a master to a substrate held by the substrate chuck.

26. The apparatus according to claim 25, wherein the lithography apparatus is constituted as an imprint apparatus or an exposure apparatus.

27. An article manufacturing method comprising:
forming a pattern on a substrate using a lithography apparatus defined in claim 25; and
processing the pattern-formed substrate,
wherein an article is manufactured from the processed substrate.
